(19) United States
(12) Patent Application Publication
(10) Pub. No.: US 2009/0233386 A1
(43) Pub. Date: Sep. 17, 2009

(54) METHOD FOR FORMING AN INK JETTING DEVICE

(76) Inventors: Yimin Guan, Lexington, KY (US); Burton Lee Joyner, II, Lexington, KY (US); Zachary Justin Reitmeier, Lexington, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(21) Appl. No.: 12/046,494

(22) Filed: Mar. 12, 2008

(51) Int. Cl. H01L 21/02; B21D 53/76

(52) U.S. Cl. 438/21; 29/890.1; 257/E21.002

(57) ABSTRACT

A method for forming an ink jetting device includes providing a silicon substrate having a first surface having formed thereon a plurality of electrical heater elements to form a first upper exposed surface; depositing a polymer over the first upper exposed surface to form a sacrificial polymer layer; patterning the sacrificial polymer layer to form a second exposed upper surface; depositing a conformal material over the second exposed upper surface to form a conformal nozzle layer; patterning the conformal nozzle layer to form a plurality of nozzle holes located over the electrical heater elements; patterning a mask layer to form an exposed region of the second surface of the silicon substrate that defines a location of a central ink via; etching the exposed region to form the central ink via; and removing a portion of a remainder of the polymer layer to form ink ejection chambers.

### BACKGROUND OF THE INVENTION

1. Field of the Invention

The present invention relates to a printhead, and, more particularly, to a method for forming an ink jetting device.

2. Description of the Related Art

A typical ink jet printhead includes a silicon chip to which a nozzle plate fabricated from a polymer material is attached. However, during printhead assembly, significant out-gassing and thermal contraction may occur. Also, under certain conditions the polymer nozzle plate may tend to sag, thus affecting the accuracy and repeatability of ink drop placement. Other issues with current polymer nozzle plates, for example, are difficulty with adhesion of polymer to a substrate and print quality issues associated with alignment of nozzle holes after polymer cure.

### SUMMARY OF THE INVENTION

The present invention provides a method for forming an ink jetting device that uses, for example, a sacrificial polymer layer and a single deposited conformal nozzle layer.

The terms “first” and “second” preceding an element name, e.g., first surface, second surface, etc., are used for identification purposes to distinguish between similar or related elements, results or concepts, and are not intended to necessarily imply order, nor are the terms “first” and “second” intended to preclude the inclusion of additional similar or related elements, results or concepts, unless otherwise indicated.

The invention, in one form thereof, is directed to a method for forming an ink jetting device. The method includes: providing a silicon substrate having a first surface and a second surface opposite to the first surface, the first surface having formed thereon a plurality of electrical heater elements to form a first upper exposed surface; depositing a polymer over the first upper exposed surface to form a sacrificial polymer layer; patterning the sacrificial polymer layer to remove a portion of the sacrificial polymer layer to form a second exposed upper surface; depositing a conformal material over the second exposed upper surface to form a conformal nozzle layer; patterning the conformal nozzle layer to form a plurality of nozzle holes respectively located over the plurality of electrical heater elements; applying a mask layer over the second surface of the silicon substrate; patterning the mask layer to form a plurality of mask portions and an exposed region of the second surface of the silicon substrate that defines a location of a central ink via; etching the exposed region of the second surface of the silicon substrate to form the central ink via in the silicon substrate; and removing a portion of a remainder of the polymer layer to form a plurality of ink ejection chambers.

The invention, in another form thereof, is directed to a method for forming an ink jetting device. The method includes: forming a plurality of electrical heater elements on a first surface of a silicon substrate to form a first upper exposed surface, the silicon substrate having a second surface located opposite to the first surface; depositing a polymer over the first upper exposed surface to form a sacrificial polymer layer; patterning the sacrificial polymer layer to remove a portion of the sacrificial polymer layer to form a second exposed upper surface, the second exposed tipper surface including first sacrificial polymer layer areas over the first surface of the silicon substrate and second sacrificial polymer layer areas that cover the electrical heater elements, the first sacrificial polymer layer areas and the second sacrificial polymer layer areas defining a central channel with respect to a centerline, the second sacrificial polymer layer areas covering and extending beyond the electrical heater elements toward the centerline; depositing a conformal material over the second exposed upper surface to form a conformal nozzle layer; patterning the conformal nozzle layer to form a plurality of nozzle holes, which are respectively located over the plurality of electrical heater elements; applying a mask layer over the second surface of the silicon substrate; patterning the mask layer to form a plurality of mask portions and an exposed region of the second surface of the silicon substrate that defines a location of a central ink via; etching the exposed region of the second surface of the silicon substrate to form the central ink via in the silicon substrate; and removing the second sacrificial polymer layer areas of the sacrificial polymer layer to form a plurality of ink ejection chambers respectively adjacent to the plurality of electrical heater elements and the plurality of nozzle holes.

### BRIEF DESCRIPTION OF THE DRAWINGS

The above-mentioned and other features and advantages of this invention, and the manner of attaining them, will become more apparent and the invention will be better understood by reference to the following description of an embodiment of the invention taken in conjunction with the accompanying drawings, wherein:

FIG. 1A is a diagrammatic illustration of a top view of a silicon substrate having heating elements formed thereon.

FIG. 1B is a cross section of the diagrammatic illustration of FIG. 1A taken along line 1B-1B.

FIG. 2A is a diagrammatic illustration of a top view the substrate of FIGS. 1A, 1B with a sacrificial polymer layer deposited and patterned.

FIG. 2B is a cross section of the diagrammatic illustration of FIG. 2A taken along line 2B-2B.

FIG. 3A is a diagrammatic illustration of a top view the silicon substrate and sacrificial polymer layer at the process stage of FIGS. 2A, 2B after a conformal nozzle layer is deposited and the nozzle holes formed.

FIG. 3B is a cross section of the diagrammatic illustration of FIG. 3A taken along line 3B-3B.

FIG. 4A is a diagrammatic illustration of a top view of the silicon substrate, sacrificial polymer layer, and conformal nozzle layer at the process stage of FIGS. 3A, 3B after the formation of a central ink via on the back side of the silicon substrate.

FIG. 4B is a cross section of the diagrammatic illustration of FIG. 4A taken along line 4B-4B.

FIG. 5A is a diagrammatic illustration of a top view of the silicon substrate and sacrificial polymer layer at the process stage of FIGS. 4A, 4B after removal of the sacrificial polymer layer to form the ink ejection chambers.

FIG. 5B is a cross section of the diagrammatic illustration of FIG. 5A taken along line 5B-5B.

FIGS. 6A and 6B is a flowchart of a method for forming an ink jetting device in accordance with an aspect of the present invention.

Corresponding reference characters indicate corresponding parts throughout the several views. The exemplifications set out herein illustrate one embodiment of the invention, in one form, and such exemplifications are not to be construed as limiting the scope of the invention in any manner.

### DETAILED DESCRIPTION OF THE INVENTION

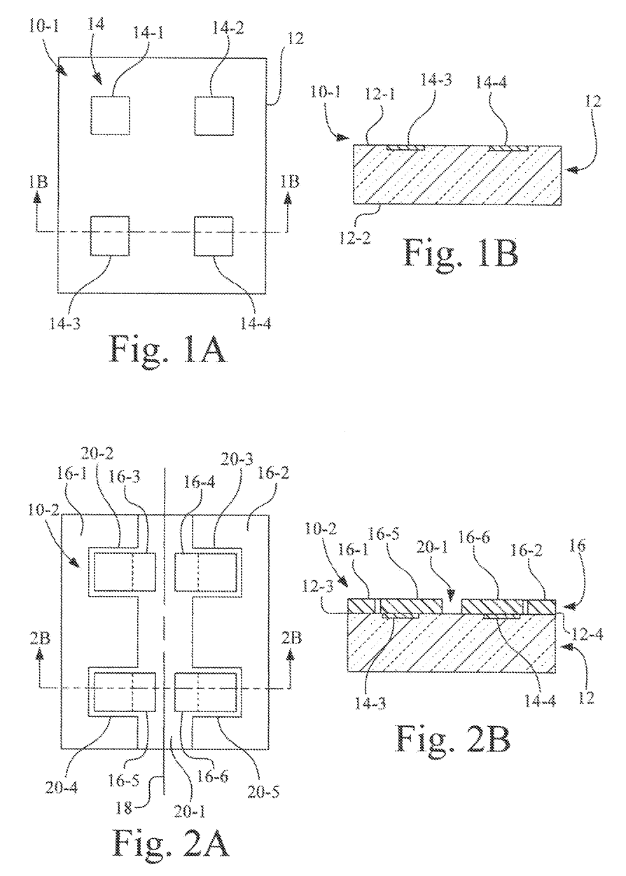

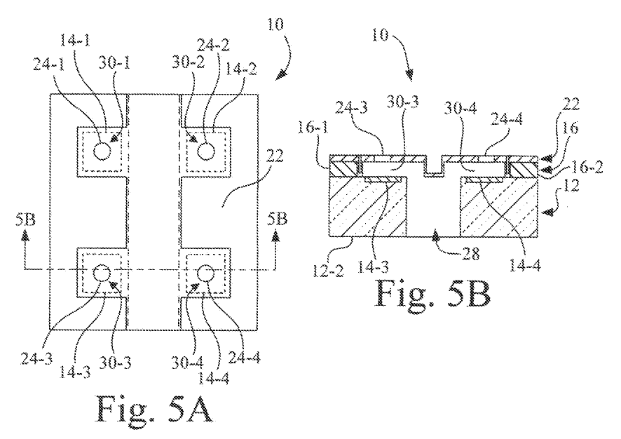

Referring now to the drawings and particularly to FIGS. 1A-5B, there is shown various fabrication stages associated with a method for forming an ink jetting device 10 (see FIG. 5B) in accordance with an aspect of the present invention. Those skilled in the art will recognize that the structures shown in FIGS. 1A-5B are exaggerated in size and shape to more clearly show fabrication aspects of the present invention.

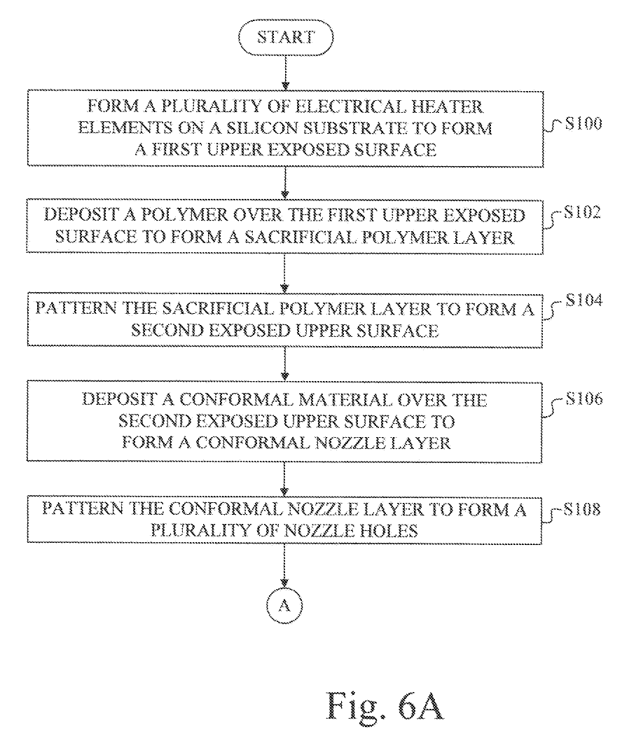

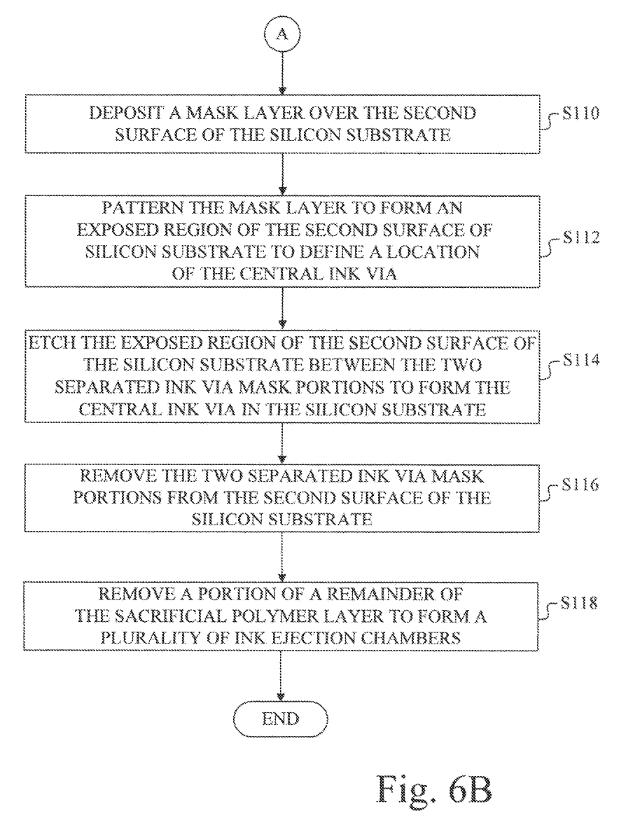

The various acts associated with the method for forming an ink jetting device 10 in accordance with the present invention are summarized in the flowchart of FIGS. 6A and 6B.

At act S100, a plurality of electrical heater elements, e.g., resistors, is formed on a silicon substrate to form a first upper exposed surface. As illustrated, for example, in FIGS. 1A and 1B, fabrication of ink jetting device 10 begins with a silicon substrate 12, e.g., such as portion of a silicon wafer. Silicon substrate 12 includes a first surface 12-1 and a second surface 12-2, and edges 12-3, 12-4. Second surface 12-2, which may be planar, is parallel to, and on an opposite side of silicon substrate 12 from, first surface 12-1, which may be planar. Silicon substrate 12 is pre-cleaned, and a plurality of metallic electrical heater elements 14, e.g., electrical heater elements 14-1, 14-2, 14-3 and 14-4, are formed on first surface 12-1 of silicon substrate 12, such as by a metal vapor deposition process, to form a first upper exposed surface 10-1. In the present example only four electrical heater elements 14 are shown, but it is to be understood that the actual number of electrical heater elements 14 may be in the hundreds or thousands.

At act S102, a polymer is deposited over the first upper exposed surface to form a sacrificial polymer layer. Referring to FIGS. 2A and 2B, a polymer is deposited over first upper exposed surface 10-1, e.g., the entirety of first surface 12-1 of silicon substrate 12 and the plurality of electrical heater elements 14, to form a sacrificial polymer layer 16. The depositing of sacrificial polymer layer 16 may be achieved, for example, by a spin-coat process.

The composition of the sacrificial polymer material forming sacrificial polymer layer 16 may be a standard photoresist material or a special polymer chosen for the process. Desirable characteristics of the sacrificial polymer material include being able to withstand temperatures necessary for deposition of a conformal nozzle layer (see act S106), and being capable of being patterned without the forming of a re-entrant profile in the sacrificial polymer layer (i.e. without the top of the trench being smaller than bottom). One example of such polymer material suitable for use as the sacrificial polymer material is polyimide.

Table 1, below is a polymer reference table that includes thermal stability information for common classes of polymers.

TABLE 1
Polymer Reference Table

| | | | | | Linear | Flexural |
|---|---|---|---|---|---|---|
| | | | | TGA | CTE | Modulus |
| Acronym | Polymer | T_{g}(° C.) | Tₘ(° C.) | Decomp T | (° C.⁻¹) | (MPa) |
| ABS | Acrylonitrile | 110-125 | — | 375 | 65-95 | 2070-4140 |
| | Butadiene styrene | | | | | |
| PMMA | Polymethylmethacrylate | 85-110 | 160 | 313 | 50-60 | 2240-3170 |
| | Acrylonitrille | 95 | 135 | — | 66 | 3450-4070 |
| PTFE | Polytetrafluoroethylene | 126 | 327 | 525 | 70-120 | 525 |
| PVDF | Polyvinylidene fluoride | −60-−20 | 170-178 | 470 | 70-142 | 1724-2896 |
| Nylon 6 | Nylon 6 | 40-87 | 210-220 | 400 | 80-83 | 2690 |
| Nylon 6,6 | Nylon 6,6 | 50 | 255-265 | 426 | 80 | 2830-3240 |
| PC | Polycardonate | 140-150 | — | 473 | 68 | 2350 |
| PBT | Polybutylene | — | 220-287 | 386 | 60-95 | 2280-2760 |
| | terephthalate | | | | | |
| PET | Polyethylene | 73-80 | 245-265 | 414 | 65 | 2410-3100 |
| | terephthalate | | | | | |
| PEEK | Polyetheretherketone | 150 | 334 | 575 | 40-108 | 3860 |
| PEI | Polyetherimide | 215-217 | — | — | 47-56 | 3310 |
| LDPE | Low Density | −25 | 98-115 | 459 | 100-220 | 240-330 |
| | Polyethylene | | | | | |
| HDPE | High Density | 60-80 | 130-137 | 469 | 59-110 | 1000-1550 |
| | Polyethylene | | | | | |
| PI | Polyimide | — | 310-365 | — | 45-56 | 3100-3450 |
| PPO | Polyphenylene Oxide | 100-142 | — | 400 | 38-70 | 2250-2760 |
| PPS | Polyphenylene Sulfide | 88 | 285-290 | 508 | 49 | 3790 |
| PP | Polypropylene | −20 | 160-175 | 417 | 81-100 | 1170-1720 |
| PS | Polystyrene | 74-109 | 240-250 | 351 | 50-83 | 2620-3380 |
| PSO | Polysulfone | 190 | — | 510 | 56 | 2690 |
| PES | Polyethersulfone | 220-230 | — | — | 55 | 2400-2620 |
| PVC | Polyvinyl Chloride | 75-105 | — | 265 | 50-100 | 2070-3450 |

In Table 1, T_{g} is glass transition temperature; Tₘ is melt temperature; TGA Decomp T is decomposition temperature determined by thermogravimetric analysis; and Linear CTE is coefficient of thermal expansion.

At act S104, the sacrificial polymer layer is patterned to form a second exposed upper surface. For example, as illustrated in FIGS. 2A and 2B, a portion of sacrificial polymer layer 16 is removed to form a second exposed upper surface 10-2 that includes first sacrificial polymer layer areas 16-1, 16-2, e.g., outer areas, over the first surface 12-1 of silicon substrate 12, as well as second separated sacrificial polymer layer areas 16-3, 16-4, 16-5 and 16-6 that cover electrical heater elements 14. As shown in FIGS. 2A and 2B, the second separated sacrificial polymer layer areas 16-3, 16-4, 16-5 and 16-6 of sacrificial polymer layer 16 cover and extend beyond electrical heater elements 14 toward a centerline 18. After sacrificial polymer layer 16 is patterned, the first sacrificial polymer layer areas 16-1, 16-2 and the second separated sacrificial polymer layer areas 16-3, 16-4, 16-5 and 16-6 define a central channel 20-1 formed symmetrical with respect to centerline 18, which extends down to first surface 12-1 of silicon substrate 12, and trenches 20-2, 20-3, 20-4 and 20-5 are formed that respectively extend from central channel 20-1 around the respective separated areas 16-3, 16-4, 16-5 and 16-6 of sacrificial polymer layer 16. Central channel 20-1 and trenches 20-2, 20-3, 20-4 and 20-5 will aid in forming ink paths used for channeling ink flow to respective ink ejection chambers when selected portions of sacrificial polymer layer 16 is removed.

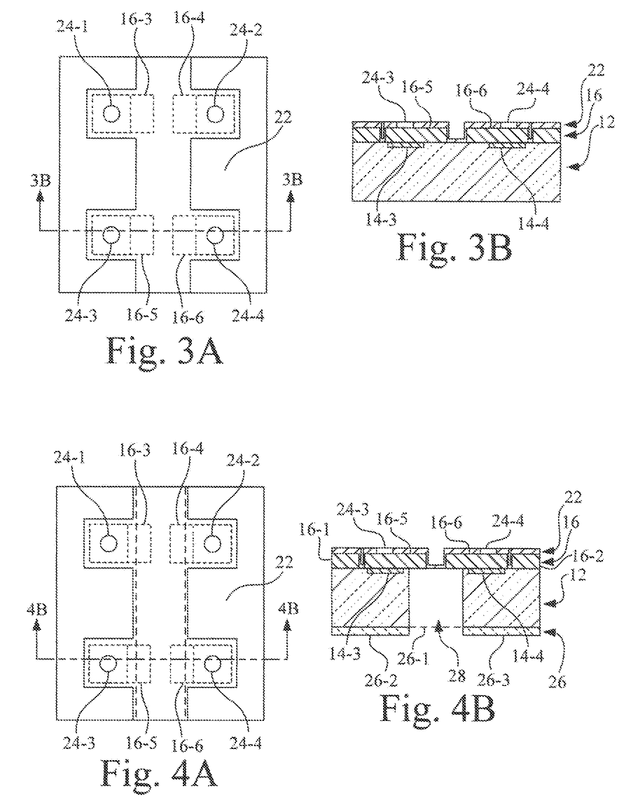

At act S106, a conformal material is deposited over the second exposed upper surface to form a conformal nozzle layer. Referring to FIGS. 3A and 3B, for example, a conformal material is deposited over the entirety of the second exposed upper surface 10-2 (see FIGS. 2A, 2B), which includes the sacrificial polymer layer areas 16-1, 16-2, 16-3, 16-4, 16-5 and 16-6; central channel 20-1; and trenches 20-2, 20-3, 20-4 and 20-5, to form a conformal nozzle layer 22.

The composition of the conformal material used in forming conformal nozzle layer 22 is selected such that the material is capable of completely filling trenches 20-2, 20-3, 20-4 and 20-5 (see FIG. 2A) formed in sacrificial polymer layer 16, since trenches 20-2, 20-3, 20-4 and 20-5 outline the walls for the ink ejection chambers. The material used in forming conformal nozzle layer 22 for the present embodiment may be a ceramic material or a metallic thin film material, such as for example, silicon oxide, silicon nitride, silicon oxynitride, polysilicon, tantalum, and gold.

At act S108, the conformal nozzle layer 22 is patterned to form a plurality of nozzle holes. For example, as illustrated in FIGS. 3A and 3B, a portion of conformal nozzle layer 22 is removed to form a plurality of nozzle holes 24-1, 24-2, 24-3, and 24-4, which extend down through conformal nozzle layer 22 to sacrificial polymer layer 16, and which are respectively located over electrical heater elements 14-1, 14-2, 14-3 and 14-4.

The formation of nozzle boles 24-1, 24-2, 24-3, and 24-4 in conformal nozzle layer 22 may be achieved by using, for example, a standard photolithography and etch processes.

At act S110, a mask layer is deposited over the second surface of the silicon substrate. Referring to FIGS. 4A and 4B, for example, a mask layer 26 is deposited over the entirety of second surface 12-2 of silicon substrate 12 (see FIG. 1B).

At act S112, the mask layer is patterned to form an exposed region of the second surface of silicon substrate to define a location of the central ink via. Referring to FIGS. 4A and 4B, for example, mask layer 26 is patterned to form an exposed region 26-1 (shown by a phantom line) that separates two ink via mask portions 26-2 and 26-3, which are located symmetrical with respect to centerline 18. Exposed region 26-1 between the ink via mask portions 26-2 and 26-3 defines a location of a central ink via 28, as best seen in FIG. 4B.

At act S114, the exposed region of the second surface of the silicon substrate between the two separated ink via mask portions is etched to form the central ink via in the silicon substrate. As best shown in FIG. 4B, for example, the exposed region 26-1 of second surface 12-2 of silicon substrate 12 between the two separated ink via mask portions 26-2 and 26-3 is etched away to form central ink via 28, which serves as a primary ink flow channel. The etching may he performed, for example, by a deep reactive ion etch (DRIE) process, a wet chemical etch, a mechanical blasting technique or some combination thereof.

At act S116, the two separated ink via mask portions are removed from the second surface of the silicon substrate. Referring to FIGS. 4B and 5B, for example, the two separated ink via mask portions 26-2 and 26-3 are remove from second surface 12-2 of silicon substrate 12.

At act S118, a portion of a remainder of the sacrificial polymer layer is removed to form a plurality of ink ejection chambers. As illustrated in FIGS. 5A and 5B, with reference to FIGS. 2A and 2B, for example, a portion (second separated sacrificial polymer layer areas 16-3, 16-4, 16-5 and 16-6) of the remainder of the sacrificial polymer layer 16 (sacrificial polymer layer areas 16-1, 16-2, 16-3, 16-4, 16-5 and 16-6) is removed to form the ink ejection chambers 30-1, 30-2, 30-3 and 30-4 of ink jetting device 10. The ink ejection chambers 30-1, 30-2, 30-3 and 30-4 are formed respectively adjacent to electrical heater elements 14-1, 14-2, 14-3 and 14-4 and to nozzle holes 24-1, 24-2, 24-3, and 24-4. The removal of second separated sacrificial polymer layer areas 16-3, 16-4, 16-5 and 16-6 of sacrificial polymer layer 16 may be achieved, for example, through oxidation during a standard oxygen-plasma photoresist-ashing process.

By using the process described above for forming ink jetting device 10, it is recognized that both fabrication of the chip (i.e., the portion including the silicon substrate) and the nozzle layer may be integrally formed in the wafer fabrication facility. Thus, the process may be completed in a single clean room, rather than shipping the wafer to a separate facility for nozzle plate attachment, thereby providing fewer opportunities for contamination. Also, the process provides improved alignment of the flow feature of the wafer and nozzle features in comparison to using a separate polymer nozzle plate that is attached to the silicon chip, as in the prior art.

By forming the conformal nozzle layer from a ceramic or metallic thin film material, the conformal nozzle layer exhibits superior rigidity over that of a polymer nozzle plate, i.e., is less likely to sag, as is commonly observed in ink jetting devices that use a polymer printhead material over the ink vias. Also, a ceramic or metallic nozzle material is more stable than a polymer film over a range of temperatures, which may reduce or eliminate out-gassing and excessive thermal contraction during processing. Furthermore, the use of a ceramic nozzle plate allows use with non-aqueous inks, if desired.

Also, the ceramic or metallic nozzle layer material is less permeable to moisture and gas, as compared to a polymer, thereby allowing the nozzle layer to also act as protective overcoat and reduce susceptibility to corrosion. This may allow for the elimination of the protective overcoat layer used on ink jetting chips of the prior art.

While this invention has been described with respect to embodiments of the invention, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A method for forming a fluid election device on a silicon substrate, said silicon substrate having a first surface and a second surface opposite to said first surface, said first surface having formed thereon a plurality of electrical heater elements to form a first upper exposed surface, the method comprising:
depositing a polymer over said first upper exposed surface to form a sacrificial polymer layer;
patterning said sacrificial polymer layer to remove a portion of said sacrificial polymer layer to form a second exposed upper surface;
depositing a conformal material over said second exposed upper surface to form a conformal nozzle layer;
patterning said conformal nozzle layer to form a plurality of nozzle holes respectively located over said plurality of electrical heater elements;
applying a mask layer over said second surface of said silicon substrate;
patterning said mask layer to form a plurality of mask portions and an exposed region of said second surface of said silicon substrate that defines a location of a central ink via;
etching said exposed region of said second surface of said silicon substrate to form said central ink via in said silicon substrate; and
removing a portion of a remainder of said polymer layer to form a plurality of ejection chambers.

2. The method of claim 1, wherein said polymer used in forming said sacrificial polymer layer has characteristics selected to withstand temperatures necessary for deposition of said conformal nozzle layer.

3. The method of claim 2, wherein said polymer used in forming said sacrificial polymer layer has characteristics selected to allow patterning without forming a re-entrant profile in said sacrificial polymer layer.

4. The method of claim 1, wherein said second exposed upper surface includes first sacrificial polymer layer areas over said first surface of said silicon substrate and second sacrificial polymer layer areas that cover said electrical heater elements, said first sacrificial polymer layer areas and said second sacrificial polymer layer areas defining a central channel formed symmetrical with respect to a centerline, said second sacrificial polymer layer areas covering and extending beyond said electrical heater elements toward said centerline.

5. The method of claim 4, wherein said portion of said remainder of said polymer layer is said second sacrificial polymer layer areas.

6. The method of claim 1, wherein said conformal material is one of a ceramic and a metallic thin film material.

7. The method of claim 1, wherein said conformal material is one of silicon oxide, silicon nitride, silicon oxynitride, polysilicon, tantalum, and gold.

8. The method of claim 1, wherein said plurality of nozzle holes is formed in said conformal nozzle layer by photolithography and etch processes.

9. The method of claim 1, wherein said exposed region of said second surface of said silicon substrate is etched by a deep reactive ion etch process to form said central via in said silicon substrate.

10. The method of claim 1, wherein said portion of said remainder of said polymer layer is removed by an oxygen-plasma photoresist-ashing process.

11. The method of claim 1, wherein said plurality of ejection chambers is formed respectively adjacent to said plurality of electrical heater elements and said plurality of nozzle holes.

12. The method of claim 1, further comprising removing said plurality of mask portions from said second surface of said silicon substrate.

13. A method for forming a fluid ejection device, comprising:
forming a plurality of electrical heater elements on a first surface of a silicon substrate to form a first upper exposed surface, said silicon substrate having a second surface located opposite to said first surface;
depositing a polymer over said first upper exposed surface to form a sacrificial polymer layer;
patterning said sacrificial polymer layer to remove a portion of said sacrificial polymer layer to form a second exposed upper surface, said second exposed upper surface including first sacrificial polymer layer areas over said first surface of said silicon substrate and second sacrificial polymer layer areas that cover said electrical heater elements, said first sacrificial polymer layer areas and said second sacrificial polymer layer areas defining a central channel with respect to a centerline, said second sacrificial polymer layer areas covering and extending beyond said electrical heater elements toward said centerline;
depositing a conformal material over said second exposed upper surface to form a conformal nozzle layer;
patterning said conformal nozzle layer to form a plurality of nozzle boles, which are respectively located over said plurality of electrical heater elements;
applying a mask layer over said second surface of said silicon substrate;
patterning said mask layer to form a plurality of mask portions and an exposed region of said second surface of said silicon substrate that defines a location of a central via;
etching said exposed region of said second surface of said silicon substrate to form said central via in said silicon substrate; and
removing said second sacrificial polymer layer areas of said sacrificial polymer layer to form a plurality of ejection chambers respectively adjacent to said plurality of electrical heater elements and said plurality of nozzle holes.

14. The method of claim 13, wherein said polymer used in forming said sacrificial polymer layer has characteristics selected to withstand temperatures necessary for deposition of said conformal nozzle layer.

15. The method of claim 14, wherein said conformal material is one of a ceramic and a metallic thin film material.

16. The method of claim 13, wherein said conformal material is one of silicon oxide, silicon nitride, silicon oxynitride, polysilicon, tantalum, and gold.

17. The method of claim 13, wherein said plurality of nozzle holes is formed in said conformal nozzle layer by photolithography and etch processes.

18. The method of claim 13, wherein said exposed region of said second surface of said silicon substrate is etched by a deep reactive ion etch process to form said central via in said silicon substrate.

19. The method of claim 13, wherein said second sacrificial polymer layer areas are removed by an oxygen-plasma photoresist-ashing process.

20. A method for forming a thermal fluid ejection device, comprising:
forming a plurality of electrical heater elements on a first surface of a silicon substrate to form a first exposed upper surface, said silicon substrate having a second surface located opposite said first surface;
depositing a polymer over at least a portion of said first upper exposed surface to form a sacrificial polymer layer;
removing a portion of said sacrificial polymer layer to form a second exposed upper surface;
depositing a conformal material over at least a portion of said second exposed upper surface to form a conformal nozzle layer;
forming a nozzle hole over each of said plurality of electrical heater elements;
applying a mask layer to said second surface of said silicon substrate;
patterning said mask layer to form a plurality of mask portions and an exposed region of said second surface of said silicon substrate, said exposed region defining a via;
etching said via into said silicon substrate; and
removing at least a portion of said polymer layer to form a plurality of ejection chambers.
